(19) United States
(12) Patent Application Publication
(10) Pub. No.: US 2017/0153814 A1
(43) Pub. Date: Jun. 1, 2017

(54) ACCESS METHOD OF A STORAGE DEVICE HAVING A HETEROGENEOUS NONVOLATILE MEMORY

(71) Applicant: SAMSUNG ELECTRONICS CO., LTD., SUWON-SI (KR)

(72) Inventors: JUNGHWAN Ryu, Suwon-Si (KR); Youngjin Cho, Seoul (KR); Hee Hyun Nam, Seoul (KR); Han-Ju Lee, Hwaseong-si (KR)

(21) Appl. No.: 15/360,144

(22) Filed: Nov. 23, 2016

(30) Foreign Application Priority Data
Nov. 27, 2015 (KR) 10-2015-0167583

(51) Int. Cl. G06F 3/06; G11C 14/00; G06F 12/02

(52) U.S. Cl. CPC G06F 3/061; G06F 12/0238; G06F 3/0655; G06F 3/0685; G11C 14/0045; G11C 14/0036; G06F 2212/202; G06F 2212/401

(57) ABSTRACT

An access method of a storage device including heterogeneous nonvolatile memories includes receiving write-requested data; and writing the data in a first memory device or a second memory device based on a characteristic of the data, wherein the first memory device is capable of performing an overwrite operation and the second memory device is incapable of performing the overwrite operation.

### CROSS-REFERENCE TO RELATED APPLICATION

This U.S. Non-provisional Patent Application claims priority under 35 U.S.C. §119 to Korean Patent Application No. 10-2015-0167583, filed on Nov. 27, 2015, the disclosure of which is incorporated by reference herein in its entirety.

### TECHNICAL FIELD

The inventive concept relates to semiconductor memories, and more particularly, to an access method of a storage device having a heterogeneous nonvolatile memory.

### DISCUSSION OF RELATED ART

A semiconductor memory device may be embodied using a semiconductor such as silicon (Si), germanium (Ge), gallium arsenide (GaAs), indium phospide (InP), etc. A semiconductor memory device may be classified as a volatile semiconductor memory device or a nonvolatile semiconductor memory device.

Certain nonvolatile memory devices are capable of performing an overwrite operation, while others are not. For example, NAND flash memories cannot perform an overwrite operation. However, a phase-change random access memory (PRAM), a resistive RAM (ReRAM), a ferroelectric RAM (FRAM), and a spin-transfer torque magnetic RAM (STT-MRAM) can perform an overwrite operation. A nonvolatile memory with overwrite capability can be randomly accessed and its read and write speeds are faster than those of a NAND flash memory. However, in terms of storage capacity, a nonvolatile memory with overwrite capability is lesser than that compared to a NAND flash memory.

Storage devices that include heterogeneous nonvolatile memories are being used to satisfy both the demand for speed and the demand for large storage capacity. However, since heterogeneous nonvolatile memories each include memories having different operation characteristics, a uniform access may weaken performance of the storage device.

### SUMMARY

An exemplary embodiment of the inventive concept provides an access method of a storage device including heterogeneous nonvolatile memories. The access method includes receiving write-requested data; and writing the data in a first memory device or a second memory device based on a characteristic of the data, wherein the first memory device is capable of performing an overwrite operation and the second memory device is incapable of performing the overwrite operation.

An exemplary embodiment of the inventive concept provides an access method of a storage device including heterogeneous nonvolatile memories. The access method includes receiving a data migration request, reading out migration data from a source memory corresponding to the data migration request, and writing the migration data in a first memory device or a second memory device according to a characteristic of the migration data, wherein the first memory device is capable of performing an overwrite operation and the second memory device is incapable of performing an overwrite operation.

An exemplary embodiment of the inventive concept provides a method for accessing a storage device, the method including receiving write data from a host, wherein an intended destination of the write data is a first memory device; changing the intended destination of the write data to a second memory device based on a characteristic of the write data; and storing the write data in the second memory device, wherein the second memory device cannot perform an overwrite operation and the first memory device can perform the overwrite operation.

### BRIEF DESCRIPTION OF THE DRAWINGS

The above and other features of the inventive concept will become more apparent by describing in detail exemplary embodiments thereof with reference to the accompanying drawings.

FIG. 1 is a block diagram illustrating a memory system in accordance with an exemplary embodiment of the inventive concept.

FIG. 2 is a block diagram illustrating a storage controller of FIG. 1 according to an exemplary embodiment of the inventive concept.

FIG. 3 is a flowchart illustrating a data write method according to an exemplary embodiment of the inventive concept.

FIG. 4 is a flowchart illustrating a data write method of a storage device according to an exemplary embodiment of the inventive concept.

FIG. 5 is a flowchart illustrating a data write method of a storage device according to an exemplary embodiment of the inventive concept.

FIG. 6 is a block diagram illustrating a storage device in accordance with an exemplary embodiment of the inventive concept.

FIG. 7 is a block diagram illustrating a storage device in accordance with an exemplary embodiment of the inventive concept.

FIG. 8 is a flowchart illustrating a data migration method according to an exemplary embodiment of the inventive concept.

FIG. 9 is a block diagram illustrating a storage device in accordance with an exemplary embodiment of the inventive concept.

FIG. 10 is a drawing illustrating a cell structure of a nonvolatile memory device capable of performing an overwrite operation according to an exemplary embodiment of the inventive concept.

FIGS. 11 and 12 are drawings each illustrating a nonvolatile memory cell capable of performing an overwrite operation according to an exemplary embodiment of the inventive concept.

FIG. 13 is a circuit diagram illustrating a nonvolatile memory device incapable of performing an overwrite operation according to an exemplary embodiment of the inventive concept.

### DETAILED DESCRIPTION OF THE EMBODIMENTS

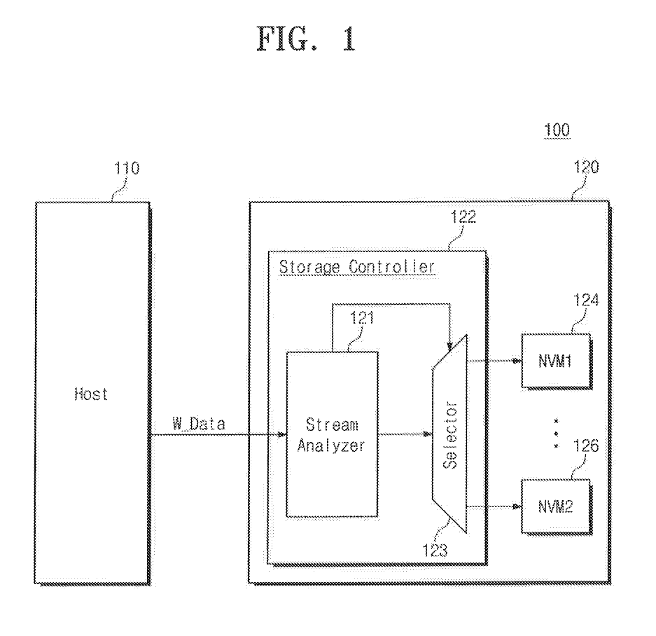

FIG. 1 is a block diagram illustrating a memory system in accordance with an exemplary embodiment of the inventive concept. Referring to FIG. 1, a memory system 100 includes a host 110 and a storage device 120. The storage device 120 may be at least one of a memory module, a memory card, a multi-chip memory, an embedded memory, and a solid state drive (SSD).

The host 110 can process data or control elements included in the memory system 100. For example, the host 110 can drive various operating systems (OSs) and execute various applications on the various OSs. The host 110 can write data to the storage device 120 or read data stored in the storage device 120. The host 110 can use the storage device 120 for a main memory or as other means of storage.

The host 110 can provide write data W_Data to the storage device 120. The host 110 can generate an address of the storage device 120. The host 110 generates a logical address of the storage device 120 and requests the storage device 120 to write the write data W_Data in a specific memory area according to the generated logical address. For example, the host 110 can provide an address corresponding to a first nonvolatile memory 124 and write data W_Data.

The storage device 120 includes a storage controller 122 and heterogeneous nonvolatile memory devices 124 and 126. The storage controller 122 can analyze a stream of data write-requested from the host 110 and select a target memory of the write-requested data according to an analysis result. In other words, even if an address provided from the host 110 corresponds to a second nonvolatile memory device 126, the first nonvolatile memory device 124 may be selected as a target memory according to the stream analysis result. In this case, the storage controller 122 has an authority to correct an address mapping table.

To have the function described above, the storage controller 122 may include a stream analyzer 121 and a selector 123. The stream analyzer 121 can analyze a characteristic of write-requested data W_Data. For example, the stream analyzer 121 can analyze a pattern of the write-requested data W_Data. The stream analyzer 121 can determine whether the write-requested data W_Data is compressed data. The stream analyzer 121 may be a device that performs a data compression on the write-requested data W_Data. In this case, the stream analyzer 121 may control the selector 123 according to a compression result.

A case in which the stream analyzer 121 analyzes a pattern of the write-requested data W_Data will be described as an example. In a case where the pattern of the write-requested data W_Data is detected as a sequential pattern, the stream analyzer 121 can control the selector 123 so that the write-requested data W_Data is written to the second nonvolatile memory device 126. The second nonvolatile memory device 126 may be incapable of performing an overwrite operation. If the pattern of the write-requested data W_Data is detected as a random pattern, the stream analyzer 121 can control the selector 123 so that the write-requested data W_Data is written to the first nonvolatile memory device 124. The first nonvolatile memory device 124 may be capable of performing an overwrite operation. However, the stream analyzer 121 may chose to write data different than that described above depending on a particular case.

The stream analyzer 121 can determine whether the write-requested data W_Data is hot data, which is frequently updated, or cold data. In a case where the write-requested data W_Data is hot data, it may be efficient to store the write-requested data W_Data in the first nonvolatile memory device 124, which is capable of performing an overwrite operation.

The first nonvolatile memory device 124 includes nonvolatile memory devices capable of performing an overwrite operation. For example, the first nonvolatile memory device 124 may be at least one of a NOR flash memory, a phase-change random access memory (PRAM), a resistive RAM (ReRAM), and a ferroelectric RAM (FRAM), a spin-transfer torque magnetic RAM (STT-RAM), etc.

The second nonvolatile memory device 126 may include, for example, a NAND flash memory device. The second nonvolatile memory device 126 may include a three-dimensional memory array. The 3D memory array may be monolithically formed in one or more physical levels of arrays of memory cells having an active area disposed above a silicon substrate and circuitry associated with the operation of those memory cells, whether such associated circuitry is above or within such substrate. The term “monolithic” may mean that layers of each level of the array are directly deposited on the layers of each underlying level of the array.

In an exemplary embodiment of the present inventive concept, the 3D memory array includes vertical NAND strings that are vertically oriented such that at least one memory cell is located over another memory cell. The at least one memory cell may comprise a charge trap layer. Each vertical NAND string may include at least one select transistor located over memory cells, the at least one select transistor having the same structure with the memory cells and being formed monolithically together with the memory cells.

The following patent documents, which are incorporated by reference herein in their entireties, describe configurations of three-dimensional memory arrays, in which a three-dimensional memory array is configured in a plurality of levels, with word lines and/or bit lines shared between the levels: U.S. Pat. Nos. 7,679,133; 8,553,466; 8,654,587; 8,559,235; and U.S. Pat. Pub. No. 2011/0233648.

The storage device 120 as described above can select a target memory according to a data characteristic independently from an address designated by the host 110. Accordingly, the storage device 120 can select a storage medium having the highest storage efficiency according to a data characteristic that cannot be sufficiently monitored in the host 110.

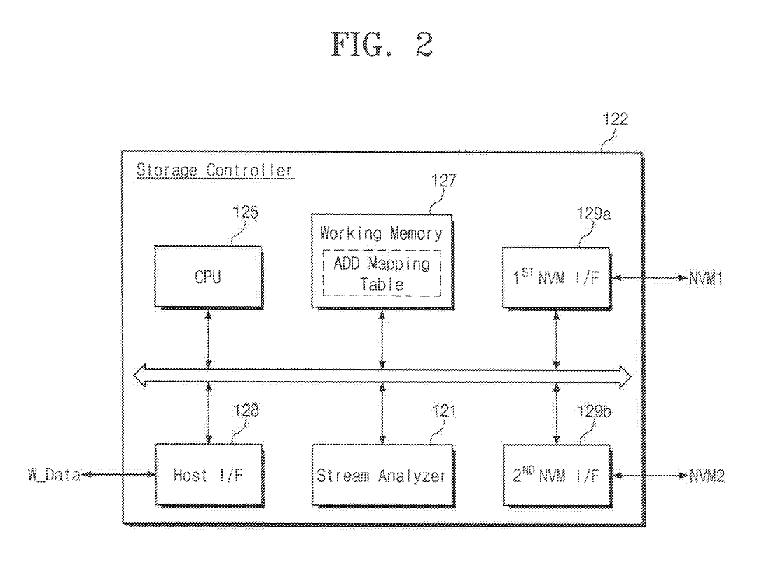

FIG. 2 is a block diagram illustrating a storage controller of FIG. 1 according to an exemplary embodiment of the inventive concept. Referring to FIG. 2, the storage controller 122 may include a stream analyzer 121, a central processing unit

(CPU) 125, a host interface 128, a working memory 127 and first and second NVM interfaces 129a and 129b. It is to be understood that more than two NVM interfaces may be included in the storage controller 122. For example, when more than two nonvolatile memories are included in the storage device 120 of FIG. 1, a corresponding number of NVM interfaces may be included in the storage controller 122.

The stream analyzer 121 can analyze a characteristic of write data W_Data provided from the host 110. For example, the stream analyzer 121 can analyze a pattern of the write data W_Data. The stream analyzer 121 can determine whether the pattern of the write data W_Data is a sequential pattern or a random pattern, and can select a target memory device in which the write data W_Data will be stored according to a determination result.

The CPU 125 can transmit a variety of information used to access the nonvolatile memory devices 124 and 126 to the host interface 128 and the first and second NVM interfaces 129a and 129b. The CPU 125 may operate according to firmware or software to perform various control operations that occur inside the storage controller 122. For example, the CPU 125 can execute a garbage collection for managing the nonvolatile memory devices 124 and 126 or software (or firmware) for performing an address mapping, a wear leveling, etc.

The working memory 127 stores a program driven in the CPU 125 or data for driving a program. In the working memory 127, an address mapping table that can be adjusted in the storage controller 122 according to a data characteristic may be included. It is assumed that the host 110 provides an address corresponding to the first nonvolatile memory device 124 in which the write data W_Data is to be written. However, the write data W_Data may be written to the second nonvolatile memory device 126 according to a determination of the stream analyzer 121 of the storage controller 122.

The host interface 128 can perform a communication with the host 110. For example, the host interface 128 provides a communication channel with the host 110. The host interface 128 also provides a physical connection to the host 110 and the storage device 120. In other words, the host interface 128 provides an interfacing with the storage device 120 in response to a bus format of the host 110. The bus format of the host 110 may be at least one of a universal serial bus (USB), a small computer small interface (SCSI), a peripheral component interconnect-express (PCI-E), an advanced technology attachment (ATA), a serial-ATA (SATA), a parallel-ATA (PATA), a serial attached SCSI (SAS), a universal flash storage (UFS), a double data rate (DDR), a DDR2, a DDR3, a DDR4, and a low power DDR (LPDDR).

The NVM interfaces 129a and 129b provide a communication channel with the nonvolatile memory devices 124 and 126. The NVM interfaces 129a and 129b may provide a physical means for data exchange with the nonvolatile memory devices 124 and 126. The first NVM interface 129a can transmit write data W Data to the first nonvolatile memory device 124 selected by the stream analyzer 121. If the second nonvolatile memory device 126 is selected by the stream analyzer 121, the second NVM interface 129b may be used.

Through the structure described above, the storage controller 122 can analyze a characteristic of the write data W_Data provided from the host 110 to adjust an address independently from an address designation of the host 110. For example, a storage medium having better performance may be selected according to the characteristic of the write data W_Data in contrast to that selected by the host 110.

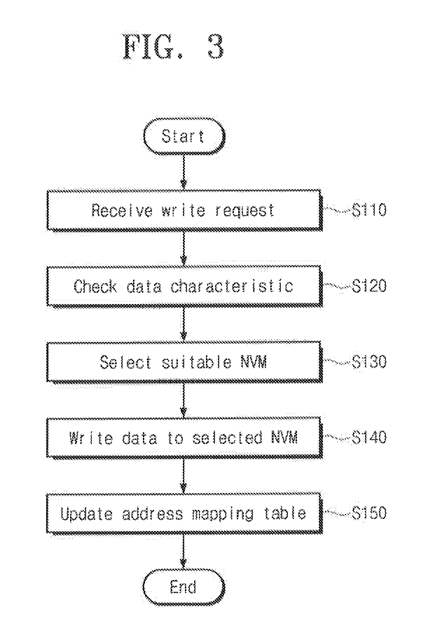

FIG. 3 is a flowchart illustrating a data write method according to an exemplary embodiment of the inventive concept. Referring to FIGS. 1 to 3, the storage controller 122 can detect a characteristic of data write-requested from the host 110 to determine a target memory.

In an operation S110, the storage controller 122 receives a write request from the host 110. The host 110 provides an address in which write data will be stored and a stream ID together with the write data W_Data.

In an operation S120, the stream analyzer 121 analyzes a characteristic of the write data W_Data received from the host 110. Here, the characteristic of the write data W_Data may be a data pattern that indicates whether the write data W_Data is data sequentially transmitted or not. The characteristic of the write data W_Data may indicate whether the write data W_Data is compressed or not. The characteristic of the write data may indicate whether the white data W_Data is hot data.

In an operation S130, a suitable storage medium is selected according to a characteristic of write data W_Data determined by the stream analyzer 121. For example, in a case where it is determined that a pattern of the write data W_Data is a sequential pattern, the stream analyzer 121 can select the second nonvolatile memory device 126 as the storage medium in which the write data W_Data will be stored. In a case where it is determined that the write data W_Data is compressed data, the stream analyzer 121 can select the first nonvolatile memory device 124 as the storage medium in which the write data W_Data will be stored. In a case where it is determined that the write data W Data is hot data, the stream analyzer 121 can select the first nonvolatile memory device 124 as the storage medium to which the write data W_Data will be stored.

In an operation S140, the storage controller 122 writes write data W_Data to the storage medium selected from the nonvolatile memory devices 124 and 126.

In an operation S150, the storage controller 122 updates an address mapping table with an address determined by the stream analyzer 121. In the address mapping table, a corresponding relationship between a logical address provided from the host 110 and a physical address of the nonvolatile memory devices 124 and 126 may be managed. However, an address provided from the host 110 may be changed by the stream analyzer 121. Thus, after the write data W_Data is written to the changed address, an update of the changed address occurs.

A selection method of a storage medium in accordance with a characteristic of write data was just described. Here, a new storage medium may be selected in the storage device 120 independently from an address provided from the host 110 or a stream ID may be adjusted. For example, rather than determining a characteristic of write data in a level of the host 110, the storage device includes the stream analyzer 121 to perform this task. The ability to analyze a data characteristic in the storage device 120 independently from the host 110 and then select an optimum storage medium according to an analysis result is more efficient than using the host for one or more of these processes.

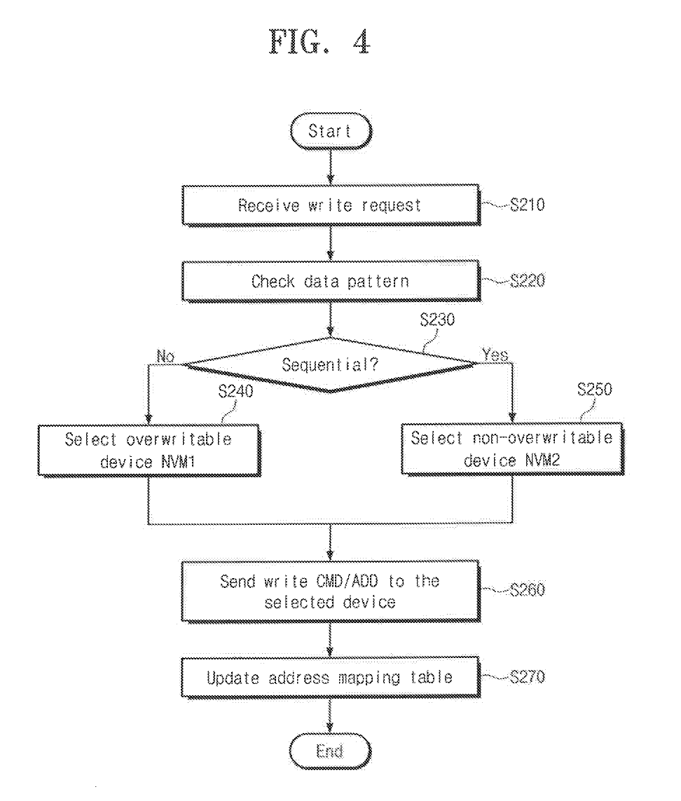

FIG. 4 is a flowchart illustrating a data write method of a storage device according to an exemplary embodiment of the inventive concept. Referring to FIG. 4, the stream analyzer 121 analyzes a pattern of data to select a storage medium.

In an operation S210, the storage controller 122 receives a write request from the host 110. The host 110 may provide an address in which write data will be stored and a stream ID together with write data W_Data.

In an operation S220, the stream analyzer 121 analyzes a pattern of the write data W_Data received from the host 110. The stream analyzer 121 can analyze a logical address provided together with the write data W_Data to determine whether the write data W_Data has a sequential write pattern or a random write pattern. Various detection methods may be used as an algorithm to analyze a pattern of the write data W_Data. For example, if a size of data that is sequentially inputted is smaller than a specific size (e.g., 16 KB), the data may be recognized as a random pattern. To analyze a write pattern, an algorithm such as a least recently used (LRU), a clean-first LRU (CFLRU), a clock algorithm (CA), a second chance (SC), and a multi-dimensional hashing (MDH) may be used. However, an analysis method of the write pattern is not limited to the methods just described above.

In an operation S230, a pattern analysis result is made by the stream analyzer 121. If a pattern of the write data W_Data is a random pattern (No direction in FIG. 4), the procedure goes to an operation S240. However, if a pattern of the write data

W_Data is a sequential pattern (Yes direction in FIG. 4), the procedure goes to an operation S250.

In the operation S240, the storage controller 122 selects the first nonvolatile memory device 124 capable of performing an overwrite operation. For example, the storage controller 122 determines that it is more efficient to store data having a random write pattern in a memory device capable of performing an overwrite operation.

In the operation S250, the storage controller 122 selects the second nonvolatile memory device 126 incapable of performing an overwrite operation. For example, the storage controller 122 determines that it is more advantageous in terms of speed to store data having a sequential write pattern in a memory device incapable of performing an overwrite operation.

In an operation S260, the storage controller 122 transmits an instruction (CMD) and an address (ADD) for writing write data to storage medium selected from the nonvolatile memory devices 124 and 126.

In an operation S270, the storage controller 122 updates an address mapping table with an address determined by the stream analyzer 121. In the address mapping table, a mapping relationship between a logical address provided from the host 110 and a physical address of the nonvolatile memory devices 124 and 126 may be maintained and managed. The storage controller 122 maps a physical address determined by the stream analyzer 121 to a logical address in the address mapping table. For example, if the address determined by the stream analyzer 121 is different from the one provided from the host 110, this change is reflected in the address mapping table.

A selection method of a storage medium in accordance with a pattern of write data W-Data was just described. According to a pattern of the write data W Data, a new storage medium may be selected or a stream ID may be adjusted.

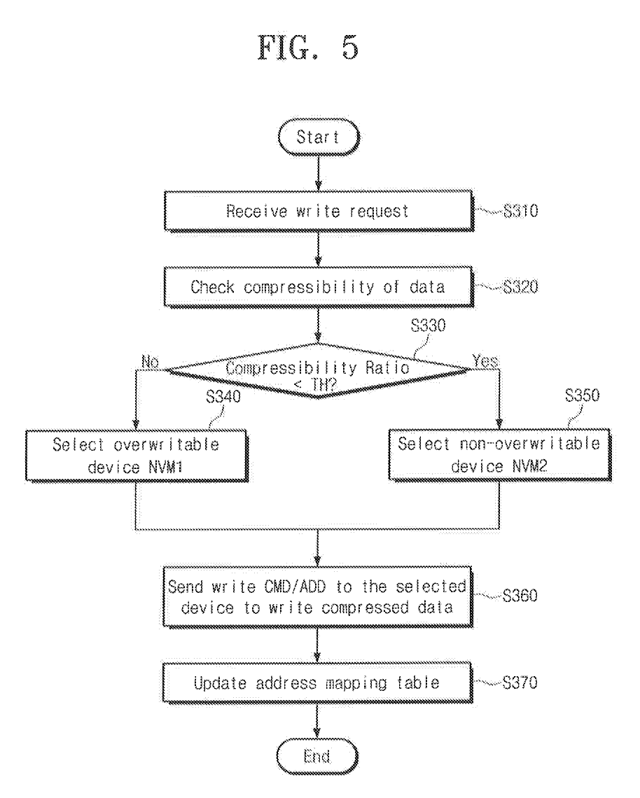

FIG. 5 is a flowchart illustrating a data write method of a storage device according to an exemplary embodiment of the inventive concept. Referring to FIG. 5, the stream analyzer 121 can analyze a compression ratio of data to select a storage medium.

In an operation S310, the storage controller 122 receives a write request from the host 110. The host 110 may provide an address in which write data will be stored and a stream ID together with write data W_Data.

In an operation S320, the stream analyzer 121 checks a compression ratio of the write data W_Data received from the host 110. Before that, a step of determining whether or not to compress data in the storage controller 122 and a step of compressing write data W_Data according to a specific compression algorithm may be performed.

The write data W_Data may be provided in a compressed state from the host 110. The stream analyzer 121 checks a compression ratio or whether the write data W_Data is compressed. Herein, a method of checking a compression ratio that represents a ratio between original data and compressed data is used. However, just checking whether data is compressed may be performed in this operation.

In an operation S330, a compression ratio analysis is made by the stream analyzer 121. If a compression ratio of the write data W_Data is not smaller than a threshold value (TH) (No direction in FIG. 5), the procedure goes to an operation S340. If a compression ratio of the write data W_Data is not greater than the threshold value (TH) (Yes direction in FIG. 5), the procedure goes to an operation S350.

In the operation S340, the storage controller 122 selects the first nonvolatile memory device 124 capable of performing an overwrite operation. In other words, in a case where the compression ratio is greater than the threshold value (TH), it is determined that it is more efficient to store write data in a memory device capable of performing an overwrite operation.

In the operation S350, the storage controller 122 selects the second nonvolatile memory device 126 incapable of performing an overwrite operation. In other words, in a case where the compression ratio is less than the threshold value (TH), it is determined that it is more advantageous in terms of speed to store write data which may not be compressed or write data having a compression ratio smaller than the threshold value (TH) in a memory device incapable of performing an overwrite operation.

In an operation S360, the storage controller 122 transmits an instruction and an address for writing write data to storage medium selected from the nonvolatile memory devices 124 and 126.

In an operation S370, the storage controller 122 updates the address mapping table with an address determined by the stream analyzer 121. The storage controller 122 maps a physical address determined by the stream analyzer 121 to a logical address in the address mapping table.

A selection method of a storage medium based on a compression ratio of write data was just described. However, in the operation S330, an operation branching off to operation S340 or S350 may depend on only whether the write data was compressed. For example, as discussed above, if the write data is not compressed, the write data may be written to a memory device incapable of performing an overwrite operation.

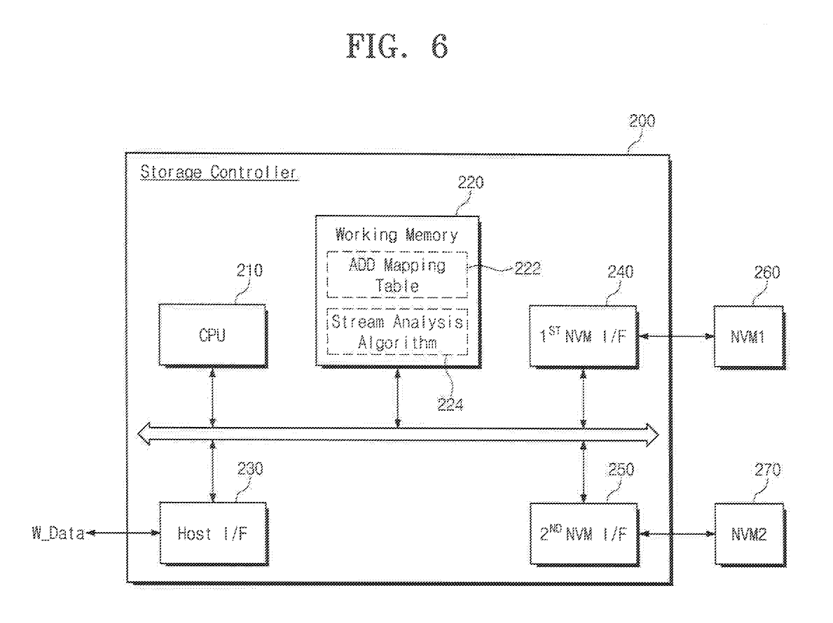

FIG. 6 is a block diagram illustrating a storage device in accordance with an exemplary embodiment of the inventive concept. Referring to FIG. 6, the storage device may include a storage controller 200, a first nonvolatile memory device 260 capable of performing an overwrite operation, and a second nonvolatile memory device 270 incapable of performing an overwrite operation. Since the nonvolatile memory devices 260 and 270 are substantially the same as the nonvolatile memory devices 124 and 126 of FIG. 1, descriptions thereof will be omitted.

The storage controller 200 may include a CPU 210, a working memory 220, a host interface 230, and NVM interfaces 240 and 250. The storage controller 200 does not include a stream analyzer constituted by separate hardware. Instead, a stream analysis algorithm 224 may be loaded into the working memory 220 and may be executed by the CPU 210.

The CPU 210 driving the stream analysis algorithm 224 can analyze a characteristic of write data W_Data provided via the host interface 230. For example, the CPU 210 can determine whether a pattern of the write data W_Data is a sequential write pattern or a random write pattern and can select a target memory device in which the write data W_Data will be stored according to a determination result. The characteristic of the write data W_Data detected by the CPU 210 driving the stream analysis algorithm 224 may include not only a data pattern but also a compression ratio, a hot/cold characteristic and whether the write data is compressed.

A program being driven in the CPU 210 or data for driving the program may be stored in the working memory 220. An address mapping table 222 that can be adjusted according to a characteristic of data may be constituted in the working memory 220. For example, assume that an address corresponding to the first nonvolatile memory device 260 is provided from the outside to write the write data W_Data. However, the target memory of the write data W_Data may be changed to the second nonvolatile memory device 270 by the CPU 210 driving the stream analysis algorithm 224. This change result is written in the address mapping table 222 and will be referred to in a read operation later.

Since the functions and constitutions of the host interface 230 and the NVM interfaces 260 and 270 are substantially the same as those described in FIG. 2, descriptions thereof will be omitted.

Through the structure described above, the storage controller 200 can analyze a characteristic of write data W Data provided from the outside to independently adjust an address. Thus, the storage controller 200 according to an exemplary embodiment of the inventive concept can change an address or a stream IC provided from the outside, or a designation of the storage medium. A storage medium having the optimum performance for a particular data characteristic may be selected by the storage controller 200 itself.

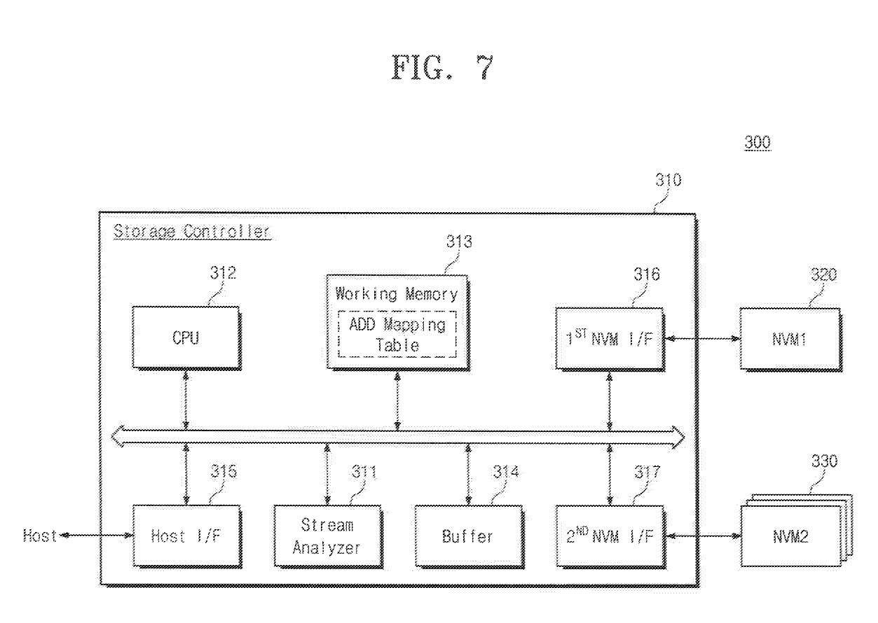

FIG. 7 is a block diagram illustrating a storage device in accordance with an exemplary embodiment of the inventive concept. Referring to FIG. 7, a storage device 300 can reset a target memory according to a characteristic of data even when data migrates according to a request of a host or its own judgment. Data migration may mean that data moves from one memory area to another memory area. The storage device 300 may include a storage controller 310 and nonvolatile memory devices 320 and 330. The storage controller 310 may include a stream analyzer 311, a CPU 312, a working memory 313, a buffer 314, a host interface 315, and NVM interfaces 316 and 317. Since the nonvolatile memory devices 320 and 330 are substantially the same as the nonvolatile memory devices 260 and 270 of FIG. 6, descriptions thereof will be omitted.

If a request for data migration occurs, the storage controller 310 reads out data from a source area of the nonvolatile memory devices 320 and 330. The data read out may be stored in the buffer 314. The data read out stored in the buffer 314 is analyzed by the stream analyzer 311. The stream analyzer 311 detects a characteristic of data to be migrated stored in the buffer 314. For example, a pattern of data to be migrated stored in the buffer 314, whether data is compressed, and whether data is hot/cold may be detected by the stream analyzer 311. Data to be migrated is called migration data M_Data.

The stream analyzer 311 selects a target memory in which migration data M_Data will be stored according to an analysis result. In a case where a pattern of the migration data M_Data is a sequential pattern, the stream analyzer 311 selects the second nonvolatile memory device 330 incapable of performing an overwrite operation as a target memory. In a case where a pattern of the migration data M_Data is a random pattern, the stream analyzer 311 selects the first nonvolatile memory device 320 capable of performing an overwrite operation as a target memory. A selection of the target memory may be applied inversely to the method described above depending on a detection result.

If a target memory of the migration data M_Data is determined and a write operation in the determined target memory is completed, the storage controller 310 updates an address mapping table. In other words, the storage controller 310 may modify an address mapping before the migration.

The CPU 312, the host interface 315, and the NVM interfaces 316 and 317 are substantially the same as the CPU 210, the host interface 230, and the NVM interfaces 240 and 250 of FIG. 6. Thus, detailed descriptions about their functions and constitutions are omitted.

A migration request may be generated from a result of various operations. For example, a migration request may occur due to a garbage collection operation for securing a free block. A migration request may also be performed in a case where a characteristic of data that exists in the buffer 314 is analyzed in a program fail situation to change the target memory. The migration request may also occur by various memory management operations.

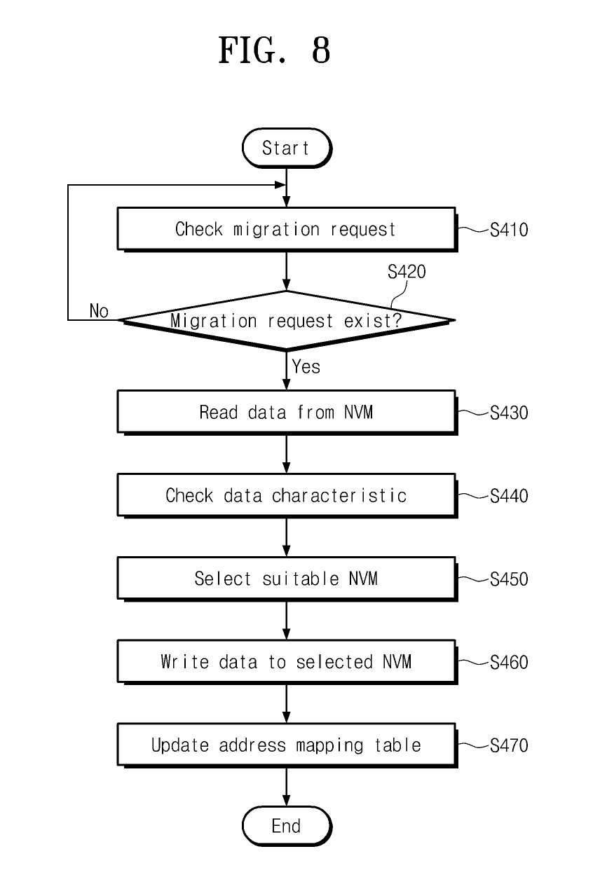

FIG. 8 is a flowchart illustrating a data migration method according to an exemplary embodiment of the inventive concept. Referring to FIG. 8, the storage controller 310 (refer to FIG. 7) may reselect a target memory according to a characteristic of migration data M Data in response to a migration request due to various memory management operations.

In an operation S410, the storage controller 310 monitors or checks for an occurrence of a migration request. As described above, the migration request may be provided from the outside of the storage controller 310 such as a request from a host. The migration request may be generated as a result of an internal garbage collection of the storage controller 310, a program fail, or a memory management operation.

In an operation S420, a determination is made as to whether a migration request occurs. If a migration request occurs, the procedure goes to an operation S430. If the migration request does not occur, the procedure goes back to the operation S410 and occurrence of the migration request is continuously monitored.

In an operation S430, the storage controller 310 reads out migration data from a source memory. The source memory of the migration data may be at least one of the nonvolatile memory devices 320 and 330. However, in a program fail situation, the data stored in a buffer may be used as a source.

In an operation S440, the storage controller 310 analyzes a characteristic of migration data M_Data stored in the source memory, for example, the buffer 314. For example, the storage controller 310 can detect a pattern of the migration data M_Data. The storage controller 310 can determine a compression ratio of the migration data M-Data, whether the migration data M_Data is compressed, and/or whether the migration data M Data is hot data or cold data.

In an operation S450, a suitable or optimum storage medium is selected according to a characteristic of the migration data M_Data determined by the storage controller 310. For example, in a case where the migration data M_Data is determined as a sequential pattern, the storage controller 310 may select the second nonvolatile memory device 330 incapable of performing an overwrite operation as a target memory in which the migration data M_Data will be written. In a case where the migration data M_Data is determined as a random pattern, the storage controller 310 may select the first nonvolatile memory device 320 capable of performing an overwrite operation as a target memory in which the migration data M_Data will be written. In a case where the migration data M_Data is hot data, e.g., frequently updated, the storage controller 310 may select the first nonvolatile memory device 320 capable of performing an overwrite operation as a target memory.

In an operation S460, the storage controller 310 writes the migration data M_Data in a memory device selected from the nonvolatile memory devices 124 and 126.

In an operation S470, the storage controller 310 updates an address mapping table with an address of a memory area in which the migration data M_Data is written.

A selection method of a storage medium in accordance with a characteristic of the migration data M_Data was just described above.

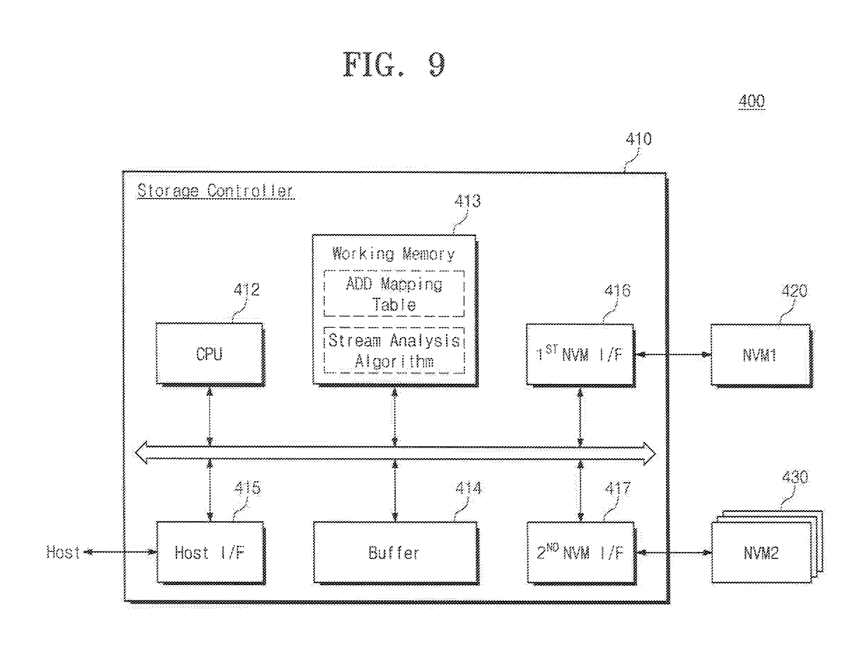

FIG. 9 is a block diagram illustrating a storage device 400 in accordance with an exemplary embodiment of the inventive concept. Referring to FIG. 9, in the storage device 400, an algorithm for performing a function of the stream analyzer 311 of

FIG. 7 may be provided in the form of software or firmware. An analysis with respect to migration data M_Data and a section of a storage medium may be performed by a CPU 412. The storage device 400 may include a storage controller 410 and nonvolatile memory devices 420 and 430. The storage controller 410 may include the CPU 412, a working memory 413, a buffer 414, a host interface 415, and NVM interfaces 416 and 417. Since the nonvolatile memory devices 420 and 430 are substantially the same as the nonvolatile memory devices 320 and 330 of FIG. 7, descriptions thereof will be omitted. Further, since the buffer 414, the host interface 415, and the NVM interfaces 416 and 417 are substantially the same as those of FIG. 7, descriptions thereof will be omitted.

The storage controller 410 can perform a data migration in accordance with a request of a host or its own judgment. For example, the CPU 412 can analyze migration data M_Data stored in the buffer 414 using a stream analysis algorithm that has been loaded into the working memory 413. If a migration request occurs, first, the storage controller 410 reads out data from a source area of the nonvolatile memory devices 420 and 430. The data read out from the source area is stored in the buffer 414.

The migration data stored in the buffer 414 is analyzed by the CPU 412. For example, a pattern of the migration data stored in the buffer 414, whether the migration data stored in the buffer 414 is compressed, and whether the migration data stored in the buffer 414 is hot data or cold data can be detected by the CPU 412. The CPU 412 selects a target memory in which the migration data M_Data will be stored according to a detection result. In a case where a pattern of the migration data M_Data is a sequential pattern, the CPU 412 selects the second nonvolatile memory device 430 incapable of performing an overwrite operation as a target memory. In a case where a pattern of the migration data M_Data is a random pattern, the CPU 412 selects the first nonvolatile memory device 420 capable of performing an overwrite operation as the target memory. Here, a selection of the target memory may be applied inversely to the method described above depending on a detection result.

If the target memory of the migration data M-Data is determined and a write of the migration data in the determined target memory is completed, the storage controller 410 updates an address mapping table constituted in the working memory 413. In other words, the storage controller 410 modifies an address mapping before the migration.

It was described above that a function of analyzing a characteristic of the migration data is embodied in the form of algorithm. It may be more economically feasible to provide software to a storage device to analyze a characteristic of the migration data rather than implementing the migration data characteristic analyzer in hardware.

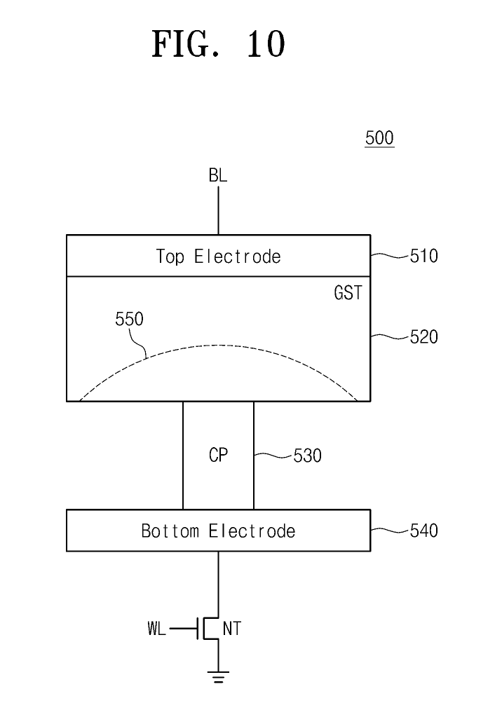

FIG. 10 is a drawing illustrating a cell structure of a nonvolatile memory device capable of performing an overwrite operation according to an exemplary embodiment of the inventive concept. A phase-change memory device is illustrated as an example of a cell structure. Referring to FIG. 10, a memory cell 500 is constituted by a variable resistor and an access transistor NT. The variable resistor is constituted by a top electrode 510, a phase change material 520, a contact plug 530, and a bottom electrode 540. The top electrode 510 is connected to a bit line BL. The bottom electrode 540 is connected between the contact plug 530 and the access transistor NT. The contact plug 530 is formed of a conductive material (e.g., TiN) and may be a heater plug. The phase change material 520 is formed between the top electrode 510 and the contact plug 530. A phase of the phase change material 520 may be changed depending on an amplitude, a duration and a fall time of a current pulse being provided thereto. A phase of a phase change material corresponding to a set or a reset is determined by an amorphous volume 550 as illustrated in FIG. 10. For example, the amorphous state corresponds to a reset state and a crystal phase corresponds to a set state. As a state changes from the amorphous state to the crystal state, the amorphous volume becomes small. The phase change material 520 has a resistance that is changed according to the formation of the amorphous volume 550. In other words, data being written is determined according to the formation of the amorphous volume 550 of the phase change material 520 according to different current pulses.

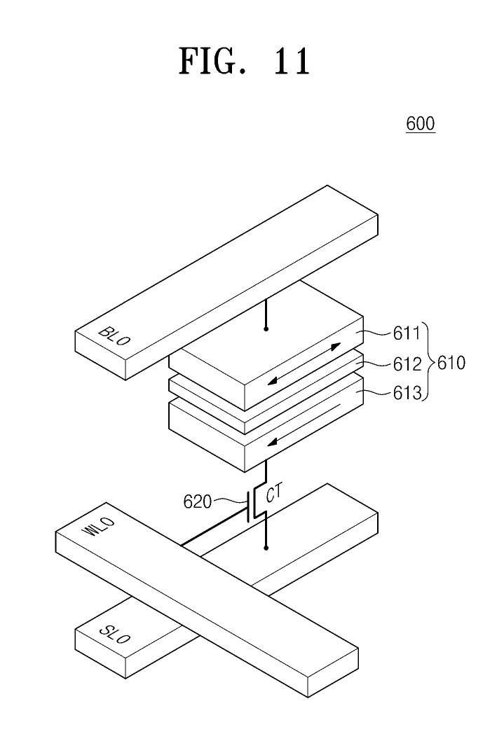

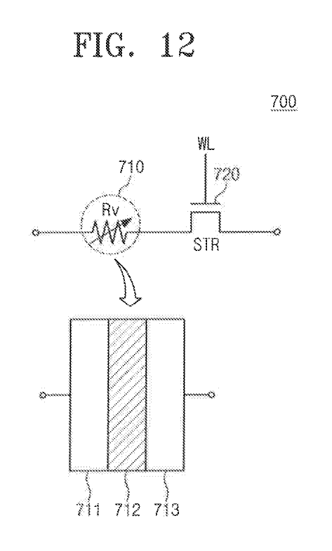

FIGS. 11 and 12 are drawings each illustrating a nonvolatile memory cell capable of performing an overwrite operation according to an exemplary embodiment of the inventive concept. In FIG. 11, a cell structure of an STT-MRAM is illustrated in three dimensions. In FIG. 12, a cell structure of an ReRAM is illustrated.

Referring to FIG. 11, a memory cell 600 of an STT-MRAM is shown as a memory cell of a nonvolatile RAM. The memory cell 600 may include a magnetic tunnel junction (MJT) device 610 and a cell transistor (CT) 620. A word line WL0 is connected to a gate of the cell transistor 620. One end of the cell transistor 620 is connected to a bit line BL0 via the MTJ device 610. The other end of the cell transistor 620 is connected to a source line SL0.

The MTJ device 610 may include a pinned layer 613, a free layer 611 and a tunnel layer 612 located between the pinned layer 613 and the free layer 611. A magnetization direction of the pinned layer 613 is fixed and a magnetization direction of the free layer 611 may be the same as the magnetization direction of the pinned layer 613 or may be the reverse of the magnetization direction of the pinned layer 613 depending on certain conditions. To fix the magnetization direction of the pinned layer 613, an anti-ferromagnetic layer may be further included.

To perform a write operation of the STT-MRAM 600, a voltage is applied to the word line WL0 to turn on the cell transistor 620 and a write current is applied between the bit line BL0 and the source line SL0. To perform a read operation of the STT-MRAM 600, data stored in the MTJ device 610 can be determined according to a resistance value that is measured by applying a turn-on voltage to the word line WL0 to turn on the cell transistor 620 and applying a read current in a direction from the bit line BL0 to the source line SL0.

FIG. 12 is a circuit diagram illustrating a memory cell 700 of a resistive memory device. Referring to FIG. 12, the memory cell 700 of the resistive memory device includes a variable resistive device Rv 710 and a selection device STR 720.

The variable resistive device Rv 710 includes a variable resistance material to store data. The selection device STR 720 supplies or cuts off a current to the variable resistive device Rv 710. The selection device STR 720 may be constituted by a MOS transistor as illustrated in FIG. 12. However, the selection device STR 720 may be constituted by a PMOS or any one of a plurality of switch devices such as a diode.

The variable resistive device Rv 710 includes a pair of electrodes 711 and 713 and a data storage layer 712 formed between the electrodes 711 and 713. The data storage layer 712 may be formed of a bipolar resistance memory material or a unipolar resistance memory material. The bipolar resistance memory material may be programmed to a set or reset state by a polarity of a pulse. The unipolar resistance memory material may be programmed to a set or reset state by a pulse of the same polarity. The unipolar resistance memory material includes a unipolar transient metal oxide such as NiOx, TiOx, etc. The bipolar resistance memory material may include perovskite system materials.

An STT-MRAM was described as an example of a memory cell constituting a nonvolatile RAM. However, a memory cell constituting the nonvolatile RAM is not limited thereto. In other words, a memory cell of the nonvolatile RAM may be provided in the form of any one of a flash memory, a PRAM, a MRAM, and a FRAM.

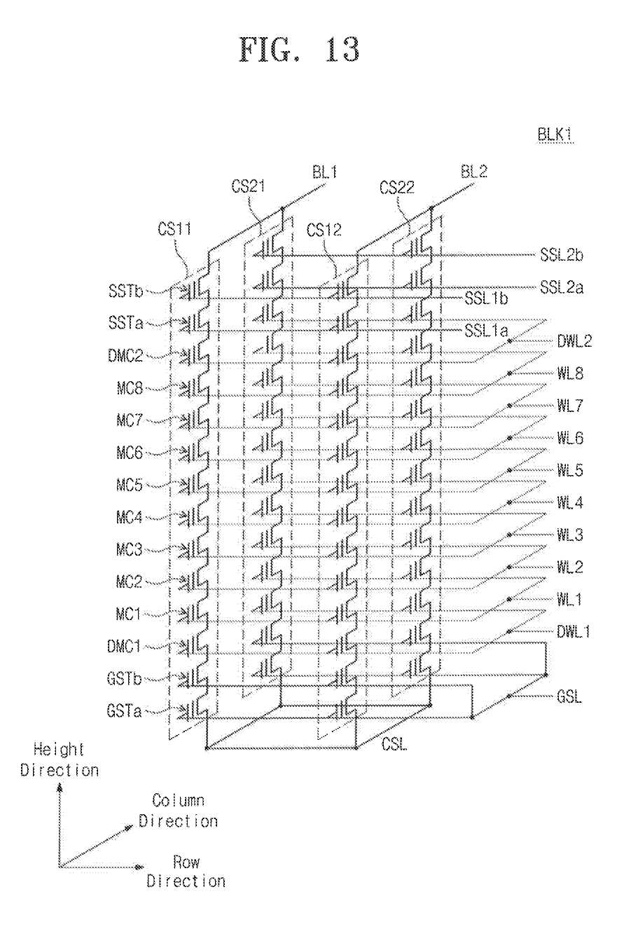

FIG. 13 is a circuit diagram illustrating a nonvolatile memory device incapable of performing an overwrite operation according to an exemplary embodiment of the inventive concept. The second nonvolatile memory device 126 of FIG. 1, which is incapable of performing an overwrite operation, includes a flash memory block BLK1 having a three dimensional structure. Other memory blocks included in the second nonvolatile memory device 126 may also have a similar structure to the memory block BLK1. However, a memory device that is incapable of performing an overwrite operation is not limited to a memory block having a three dimensional structure.

Referring to FIG. 13, the memory block BLK1 includes a plurality of cell strings (CS11, CS12, CS21, CS22). The cell strings (CS11, CS12, CS21, CS22) may be arranged along a row direction and a column direction to form rows and columns.

For example, the cell strings (CS11, CS12) may be connected to string select lines (SSL1a, SSL1b) to form a first row. The cell strings (CS21, CS22) may be connected to string select lines (SSL2a, SSL2b) to form a second row.

For example, the cell strings (CS11, CS21) may be connected to a first bit line BL1 to form a first column. The cell strings (CS12, CS22) may be connected to a second bit line BL2 to form a second column.

Each of the cell strings (CS11, CS12, CS21, CS22) includes a plurality of cell transistors. For example, each of the cell strings (CS11, CS12, CS21, CS22) may include string select transistors (SSTa, SSTb), a plurality of memory cells MC1˜MC8, ground select transistors (GSTa, GSTb) and dummy memory cells (DMC1, DMC2).

Each of the cell transistors included in the cell strings (CS11, CS12, CS21, CS22) may be a charge trap flash (CTF) memory cell.

The memory cells MC1˜MC8 are serially connected and are stacked in a height direction perpendicular to a plane formed by a row direction and a column direction. The string select transistors (SSTa, SSTb) are serially connected and may be provided between the memory cells MC1˜MC8 and the bit line BL. The ground select transistors (GSTa, GSTb) are serially connected and may be provided between the memory cells MC1˜MC8 and a common source line (CSL).

The first dummy memory cell DMC1 may be provided between the memory cells MC1˜MC8 and the ground select transistors (GSTa, GSTb). The second dummy memory cell DMC2 may be provided between the memory cells MC1˜MC8 and the string select transistors (SSTa, SSTb).

The ground select transistors (GSTa, GSTb) of the cell strings (CS11, CS12, CS21, CS22) may be connected to a ground select line (GSL) in common.

Ground select transistors of the same row may be connected to the same ground select line and ground select transistors of different rows may be connected to different ground select lines. For example, the first ground select transistors GSTa of the cell strings (CS11, CS12) of the first row may be connected to a first ground select line and the first ground select transistors GSTa of the cell strings (CS21, CS22) of the second row may be connected to a second ground select line.

Additionally, ground select transistors provided at the same height from a substrate may be connected to the same ground select line and ground select transistors provided at different heights from the substrate may be connected to different ground select lines. The first ground select transistors GSTa of the cell strings (CS11, CS12, CS21, CS22) may be connected to the first ground select line and the second ground select transistors GSTb of the cell strings (CS11, CS12, CS21, CS22) may be connected to the second ground select line.

Memory cells at the same height from the ground select transistors (GSTa, GSTb) are connected to the same word line and memory cells at different heights from the ground select transistors (GSTa, GSTb) are connected to different word lines. For example, the first through eighth memory cells MC1˜MC8 of the cell strings (CS11, CS12, CS21, CS22) are connected to first through eighth word lines WL1˜WL8 respectively in common.

Among the first string select transistors SSTa of the same height, the string select transistors of the same row are connected to the same string select line and string select transistors of different rows are connected to different string select lines. For example, the first string select transistors SSTa of the first row cell strings (CS11, CS12) are connected to the string select line SSL1a in common and the first string select transistors SSTa of the second row cell strings (CS21, CS22) are connected to the string select line SSL1b in common.

Among second string select transistors SSTb of the same height, the string select transistors of the same row are connected to the same string select line and string select transistors of different rows are connected to different string select lines. For example, the second string select transistors SSTb of the first row cell strings (CS11, CS12) are connected to the string select line SSL1b in common and the second string select transistors SSTb of the second row cell strings (CS21, CS22) are connected to the string select line SSL2b in common.

Additionally, string select transistors of cell strings of the same row may be connected to the same string select line in common. For example, the first and second string select transistors (SSTa, SSTb) of the cell strings (CS11, CS12) of the first row may be connected to the same string select line in common. The first and second string select transistors (SSTa, SSTb) of the cell strings (CS21, CS22) of the second row may be connected to the same string select line in common.

Dummy memory cells of the same height are connected to the same dummy word line and dummy memory cells of different heights are connected to different dummy word lines. For example, the first dummy memory cells DMC1 are connected to a first dummy word line DWL1 and the second dummy memory cells DMC2 are connected to a second dummy word line DWL2.

In the first memory block BLK1, read and write operations may be performed by a row unit. For example, one row of the first memory block BLK1 may be selected by the string select lines (SSL1a, SSL1b, SSL2a, SSL2b).

For example, when a turn-on voltage is supplied to the string select lines (SSL1a, SSL1b) and a turn-off voltage is supplied to the string select lines (SSL2a, SSL2b), the cell strings (CS11, CS12) of the first row are connected to the bit lines (BL1, BL2) to be driven. When a turn-on voltage is supplied to the string select lines (SSL2a, SSL2b) and a turn-off voltage is supplied to the string select lines (SSL1a, SSL1b), the cell strings (CS21, CS22) of the second row are connected to the bit lines (BL1, BL2) to be driven. Memory cells of the same height are selected among memory cells of a cell string of a row driven by driving a word line. Read and write operations may be performed in the selected memory cells. The selected memory cells may form a physical page unit.

In the memory block BLK1, an erase operation may be performed by a memory block unit or a sub block unit. When an erase operation is performed by a memory block unit, all the memory cells MC of the first memory block BLK1 may be erased at the same time according to an erase request. When an erase operation is performed by a sub block unit, some of the memory cells MC of the first memory block BLK1 may be erased at the same time according to an erase request and the remaining memory cells may be erase-prohibited. A low voltage (e.g., a ground voltage) may be supplied to a word line connected to memory cells being erased and a word line connected to the erase-prohibited memory cells may be floated.

The memory block BLK1 illustrated in FIG. 13 is an example, as such, the number of cell strings may increase or decrease, and the number of rows and columns formed by cell strings may increase or decrease depending on the number of cell strings. The number of cell transistors (GST, MC, DMC, SST, etc.) of the memory block BLK1 may increase or decrease respectively and a height of the memory block BLK1 may increase or decrease depending on the number of the cell transistors. The number of lines (GSL, WL, DWL, SSL, etc.) connected to the cell transistors may increase or decrease depending on the number of the cell transistors.

A dynamic RAM (DRAM), the nonvolatile memory device, and the memory controller according to an exemplary embodiment of the inventive concept may be mounted using various types of packages. For example, the volatile and nonvolatile memory devices and/or the memory controller may be mounted using various types of packages such as package on package (PoP), ball grid array (BGA), chip scale package (CSP), plastic leaded chip carrier (PLCC), plastic dual in-line package (PIMP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSOP), thin small outline package (TSOP), system in package (SIP), multi chip package (MCP), wafer-level fabricated package (WFP) and wafer-level processed stack package (WSP).

According to an exemplary embodiment of the inventive concept, an optimum or best suited memory among heterogeneous nonvolatile memories may be selected as a target memory according to a characteristic of data being write-requested. With reference to a property, such as a pattern and a compression ratio of data that are not recognized in a host, a storage device can independently select a target memory and adjust an address mapping table. Thus, performance of a storage device, which uses heterogeneous nonvolatile memories to provide high capacity and high data speed, may increase.

While the inventive concept has been described with reference to exemplary embodiments thereof, it will be apparent to those skilled in the art that various changes and modifications may be made thereto without departing from the spirit and scope of the inventive concept.

What is claimed is:

1. A method for accessing a storage device including heterogeneous nonvolatile memories comprising:
receiving write-requested data; and
writing the data in a first memory device or a second memory device based on a characteristic of the data, wherein the first memory device is capable of performing an overwrite operation and the second memory device is incapable of performing the overwrite operation.

2. The method of claim 1, wherein the characteristic of the data corresponds to a data pattern.

3. The method of claim 2, wherein when the pattern of the data is a sequential pattern, the data is written in the second memory device.

4. The method of claim 2, wherein when the pattern of the data is a random pattern, the data is written in the first memory device.

5. The method of claim 1, wherein the characteristic of the data corresponds to a compression ratio of the data or whether the data is compressed.

6. The method of claim 5, wherein when the data is compressed data, the data is written in the first memory device and when the data is uncompressed data, the data is written in the second memory device.

7. The method of claim 5, wherein if the compression ratio of the data is greater than a reference value, the data is written in the first memory device.

8. The method of claim 1, further compressing updating an address mapping table according to the characteristic of the data.

9. The method of claim 1, wherein the first memory device comprises a NOR flash memory, a phase change random access memory (PRAM), a resistive RAM (ReRAM), a ferroelectric RAM (FRAM), a spin transfer torque magnetic RAM (STT-MRAM) and the second memory device comprises a NAND flash memory device.

10. A method for accessing a storage device including heterogeneous nonvolatile memories comprising:
receiving a data migration request;
reading out migration data from a source memory corresponding to the data migration request;
and
writing the migration data in a first memory device or a second memory device according to a characteristic of the migration data,
wherein the first memory device is capable of performing an overwrite operation and the second memory device is incapable of performing the overwrite operation.

11. The method of claim 10, wherein the source memory corresponds to the first memory device and a target memory in which the migration data is written corresponds to the second memory device.

12. The method of claim 10, wherein the characteristic of the migration data comprises a data pattern or whether the data is compressed.

13. The method of claim 12, wherein when the data pattern is a sequential pattern, the migration data is written in the second memory device.

14. The method of claim 12, wherein when the migration data is compressed data, the migration data is written in the first memory device.

15. The method of claim 10, wherein the first memory device comprises a NOR flash memory, a phase change random access memory (PRAM), a resistive RAM (ReRAM), a ferroelectric RAM (FRAM), a spin transfer torque magnetic RAM (STT-MRAM) and the second memory device comprises a NAND flash memory device.

16. A method for accessing a storage device comprising:
receiving write data from a host, wherein an intended destination of the write data is a first memory device;
changing the intended destination of the write data to a second memory device based on a characteristic of the write data; and
storing the write data in the second memory device, wherein the second memory device cannot perform an overwrite operation and the first memory device can perform the overwrite operation.

17. The method of claim 16, wherein the characteristic of the write data includes a pattern of the write data, a compression indication of the write data or an indication that the write data is frequently accessed.

18. The method of claim 16, further comprising updating an address mapping table with an address corresponding to the new destination of the write data.

19. The method of claim 16, wherein the intended destination of the write data is changed by using software or hardware.

20. The method of claim 16, wherein the second memory device includes a flash memory and the first memory device includes a phase change random access memory.
